(19) United States
(12) Patent Application Publication
(10) Pub. No.: US 2009/0230459 A1
(43) Pub. Date: Sep. 17, 2009

(54) NON-VOLATILE SEMICONDUCTOR MEMORY DEVICE AND METHOD OF MANUFACTURING THE SAME

(75) Inventors: Masaru KITO, Yokohama-shi (JP); Ryota KATSUMATA, Yokohama-shi (JP); Hiroyasu TANAKA, Tokyo (JP); Masaru KIDOH, Tokyo (JP); Yoshiaki FUKUZUMI, Yokohama-shi (JP); Hideaki AOCHI, Kawasaki-shi (JP); Yasuyuki MATSUOKA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/396,062

(22) Filed: Mar. 2, 2009

(30) Foreign Application Priority Data
Mar. 14, 2008 (JP) 2008-065900

(51) Int. Cl. H01L 29/792; H01L 29/788; H01L 21/336

(52) U.S. Cl. 257/324; 257/314; 438/257; 257/E21.409; 257/E29.3; 257/E29.309

(57) ABSTRACT

A non-volatile semiconductor memory device includes a memory string which is electrically rewritable and includes a plurality of memory cells connected in series. The memory string includes a plurality of first conductive layers which are extended parallel to a substrate and laminated; a first semiconductor layer which is formed so as to pass through the plurality of the first conductive layers; and an electric charge accumulation layer which is formed between the first conductive layer and the first semiconductor layer and is configured so as to be able to accumulate electric charge. The first conductive layer is configured by material smaller in work function than P⁺-type polysilicon.

### CROSS-REFERENCE TO RELATED APPLICATIONS

This application is based upon and claims the benefit of priority from the prior Japanese Patent Application No. 2008-65900, filed on Mar. 14, 2008, the entire contents of which are incorporated herein by reference.

### BACKGROUND OF THE INVENTION

1. Field of the Invention

The present invention relates to a non-volatile semiconductor memory device and a method of manufacturing the same, both of which are capable of electrically rewriting data.

2. Description of the Related Art

Hitherto, a large-scale integrated circuit (LSI) has been formed by integrating elements within a two-dimensional flat surface on a silicon substrate. In order to increase memory storage capacity, dimension of one element must be reduced or miniaturized. However, in recent years, its miniaturization has also become difficult in view of cost and in technique. In order to achieve miniaturization, advances in photolithography technology are required. However, for example, the rules around 40 nm are the limits of resolution in existing ArF immersion exposure technology, and an EUV exposure tool needs to be introduced for further miniaturization. However, the EUV exposure tool is costly and is not realistic in view of cost constraints. Furthermore, even if the miniaturization is achieved, unless scaling of driving voltage or the like is accomplished, it is anticipated that a withstand voltage between elements or the like reaches a physical limiting point. That is, there is a high possibility that operation as a device becomes difficult.

For this reason, in recent years, in order to enhance the integration degree of memory, semiconductor storage devices in which memory cells are three-dimensionally arranged have been proposed (see Patent document 1: Japanese Unexamined Patent Publication No. 2007-266143, Patent document 2: U.S. Pat. No. 5,599,724, Patent document 3: U.S. Pat. No. 5,707,885).

As one of the known non-volatile semiconductor memory devices in which the memory cells are three-dimensionally arranged, there is a non-volatile semiconductor memory device using a transistor with a columnar structure (see Patent documents 1 to 3). The semiconductor storage device using the transistor with the columnar structure has a conductive layer serving as a gate electrode, the conductive layer being laminated in multilayers, and a pillar-shaped columnar semiconductor which is formed so as to pass through the conductive layer. The columnar semiconductor serves as a channel (body) portion of the transistor. Memory gate insulating layers are formed around the columnar semiconductor. The memory gate insulating layers are configured so as to be able to accumulate electric charge.

Even in the non-volatile semiconductor memory device in which the memory cells are three-dimensionally arranged, advances in data retention characteristics are a problem as in a non-volatile semiconductor memory device in which memory cells are two-dimensionally arranged.

### SUMMARY OF THE INVENTION

According to one embodiment of the present invention, there is provided a non-volatile semiconductor memory device including a memory string which is electrically rewritable and includes a plurality of memory cells connected in series. The memory string includes a plurality of first conductive layers which are extended parallel to a substrate and laminated; a first semiconductor layer which is formed so as to pass through the plurality of the first conductive layers; and an electric charge accumulation layer which is formed between the first conductive layer and the first semiconductor layer and is configured so as to be able to accumulate electric charge. The first conductive layer is configured by material smaller in work function than P⁺-type polysilicon.

According to another embodiment of the present invention, there is provided a method of manufacturing a non-volatile semiconductor memory device having memory cells which are electrically rewritable and are connected in series. The method of manufacturing the non-volatile semiconductor memory device comprising: laminating a plurality of conductive layers on a substrate; forming a hole so as to pass through the plurality of the conductive layers; forming an electric charge accumulation layer on a side wall facing the hole; and forming a semiconductor layer so as to embed the hole. The conductive layer is configured by material smaller in work function than P⁺-type polysilicon.

### BRIEF DESCRIPTION OF THE DRAWINGS

FIG. 1 is a configuration schematic view showing a non-volatile semiconductor memory device 100 according to a first embodiment of the present invention;

FIG. 2 is a partially schematic perspective view showing a memory transistor region 12 of the non-volatile semiconductor memory device 100 according to the first embodiment;

FIG. 3 is a circuit diagram showing one memory string MS in the first embodiment;

FIG. 4 is a cross-sectional view showing the memory string MS of the non-volatile semiconductor memory device 100 in the first embodiment;

FIG. 5 is a cross-sectional view showing a manufacturing process of the non-volatile semiconductor memory device 100 according to the first embodiment;

FIG. 6 is a cross-sectional view showing a manufacturing process of the non-volatile semiconductor memory device 100 according to the first embodiment;

FIG. 7 is a cross-sectional view showing a manufacturing process of the non-volatile semiconductor memory device 100 according to the first embodiment;

FIG. 8 is a cross-sectional view showing a manufacturing process of the non-volatile semiconductor memory device 100 according to the first embodiment;

FIG. 9 is an energy band view for explaining effects of the non-volatile semiconductor memory device 100 according to the first embodiment; and

FIG. 10 is a cross-sectional view showing a memory string MSa of a non-volatile semiconductor memory device in a second embodiment of the present invention.

### DETAILED DESCRIPTION OF THE EMBODIMENTS

Hereinafter, one embodiment of a non-volatile semiconductor memory device according to the present invention will be described with reference to drawings.

### First Embodiment

### Configuration of Non-Volatile Semiconductor Memory Device 100 According to First Embodiment

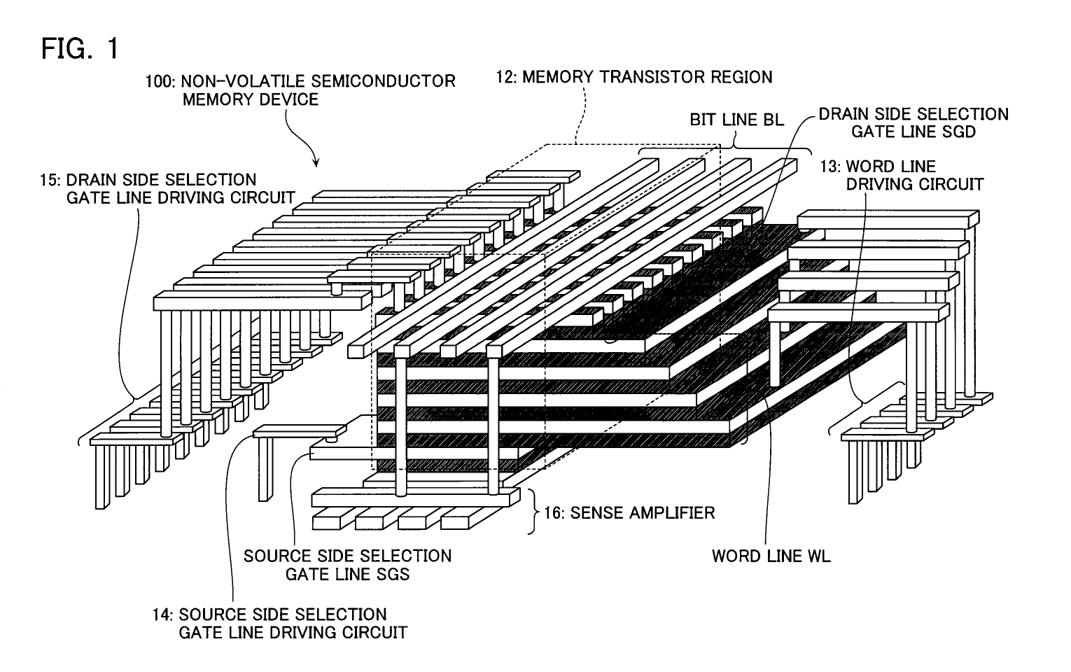

FIG. 1 shows a schematic view of a non-volatile semiconductor memory device 100 according to a first embodiment of the present invention. As shown in FIG. 1, the non-volatile semiconductor memory device 100 according to the first embodiment mainly has a memory transistor region 12, a word line driving circuit 13, a source side selection gate line (SGS) driving circuit 14, a drain side selection gate line (SGD) driving circuit 15, and a sense amplifier 16. The memory transistor region 12 has memory transistors which store data. The word line driving circuit 13 controls a voltage to be applied to a word line WL. The source side selection gate line (SGS) driving circuit 14 controls a voltage to be applied to a source side selection gate line SGS. The drain side selection gate line (SGD) driving circuit 15 controls a voltage to be applied to a drain side selection gate line (SGD). The sense amplifier 16 senses current (or potential) in the bit lines BL, amplifies it, and determines electrically stored data in the memory cell. Incidentally, in addition to the above, the non-volatile semiconductor memory device 100 according to the embodiment has a bit line driving circuit which controls a voltage to be applied to a bit line BL and a source line driving circuit which controls a voltage to be applied to a source line SL (not shown in the drawing).

As shown in FIG. 1, in the non-volatile semiconductor memory device 100 according to the first embodiment, the memory transistors, which constitute the memory transistor region 12, are formed by laminating plural semiconductor layers.

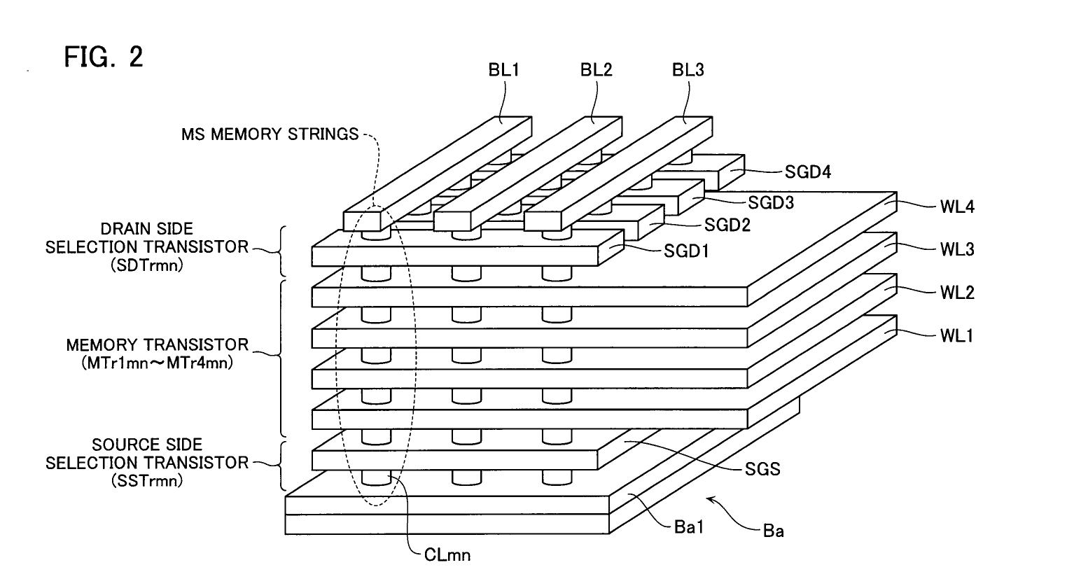

FIG. 2 is a partially schematic perspective view showing the memory transistor region 12 of the non-volatile semiconductor memory device 100 according to the first embodiment. In the embodiment, the memory transistor region 12 has m×n memory strings MS (m and n are a natural number), each memory string being composed of memory transistors MTr1mn to MTr4mn, a source side selection transistor SSTrmn, and a drain side selection transistor SDTrmn. In FIG. 2, one example having the number of m=3 and n=4 is shown. The memory transistors MTr1mn to MTr4mn are connected in series, are electrically rewritable, and store information. The source side selection transistor SSTrmn and the drain side selection transistor SDTrmn are connected in series to the memory transistors MTr1mn to MTr4mn, and control whether or not a current is to be supplied to the memory string MS.

Word lines WL1 to WL4 connected to gates of the memory transistors MTr1mn to MTr4mn of the respective memory strings MS are formed by the same conductive layers via interlayer insulating layers, respectively. Each of the word lines WL1 to WL4 is connected in common to plural memory string MS. That is, all gates of the memory transistors MTr1mn of the respective memory strings MS are connected to the wordline WL1. In addition, all gates of the memory transistors MTr2mn of the respective memory strings MS are connected to the wordline WL2. Furthermore, all gates of the memory transistors MTr3mn of the respective memory strings MS are connected to the word line WL3. Further, all gates of the memory transistors MTr4mn of the respective memory strings MS are connected to the word line WL4. In the non-volatile semiconductor memory device 100 according to the embodiment, as shown in FIGS. 1 and 2, the word lines WL1 to WL4 are formed so as to be two-dimensionally extended in a direction parallel to a semiconductor substrate Ba, respectively. Furthermore, the word lines WL1 to WL4 are arranged substantially perpendicular to the respective memory strings MS. Further, end portions in a row direction of the respective word lines WL1 to WL4 are formed in a stepwise shape. In this case, the row direction is a direction orthogonal to a lamination direction; and a column direction is a direction orthogonal to the lamination direction and the row direction.

Each memory string MS has a pillar-shaped columnar semiconductor CLmn (in the case shown in FIG. 2, m=1 to 3 and n=1 to 4) on an n⁺ region (Ba2 to be described later) formed in a P⁻ well region Ba1 of the semiconductor substrate Ba. The respective columnar semiconductors CLmn are formed in a vertical direction from the semiconductor substrate Ba, and are disposed in a matrix on the surfaces of the semiconductor substrate Ba and the word lines (WL1 to WL4). That is, the memory strings MS are disposed in the matrix within the surface perpendicular to the columnar semiconductors CLmn. Incidentally, the columnar semiconductor CLmn may be a columnar shape or a prismatic shape. Furthermore, the columnar semiconductor CLmn includes a columnar semiconductor having a stepwise shape.

In addition, as shown in FIG. 2, rectangular plate shaped drain side selection gate lines SGD (in the case shown in FIG. 2, SGD1 to SGD4) which constitute the drain side selection transistor SDTrmn are provided on the upper side of the memory string MS via the columnar semiconductors CLmn and an insulating layer (not shown in the drawing). The respective drain side selection gate lines SGD are insulatively separated from each other. Different from the word lines WL1 to WL4, the drain side selection gate lines SGD are extended in the row direction formed in line shapes repeatedly provided in the column direction. Furthermore, columnar semiconductors CLmn are formed passing through the centerline in the column direction of the drain side selection gate lines SGD.

Further, as shown in FIG. 2, the source side selection gate line SGS which constitutes a source side selection transistor SSTrmn is formed on the lower side of the memory string MS via the columnar semiconductor CLmn and an insulating layer (not shown in the drawing). The source side selection gate line SGS is formed so as to be two-dimensionally extended in a direction parallel to the semiconductor substrate Ba as in the word lines WL1 to WL4. Incidentally, in addition to the structure as shown in FIG. 2, the source side selection gate line SGS may be a stripe shape which is extended in the row direction with being repeatedly formed in the column direction.

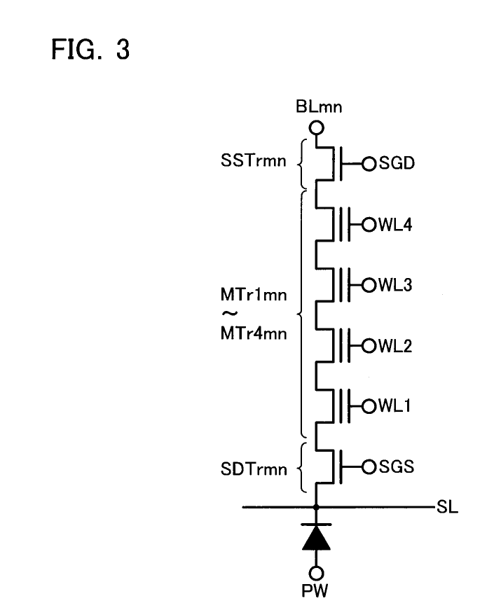

Next, a circuit configuration configured by the memory string MS in the first embodiment and operation thereof will be described with reference to FIGS. 2 and 3. FIG. 3 is a circuit diagram of one memory string MS in the first embodiment.

As shown in FIGS. 2 and 3, in the first embodiment, the memory string MS has four memory transistors MTr1mn to MTr4mn, the source side selection transistor SSTrmn, and the drain side selection transistor SDTrmn. These four memory transistors MTr1mn to MTr4mn, the source side selection transistor SSTrmn, and the drain side selection transistor SDTrmn are connected in series, respectively (see FIG. 3). In the memory string MS of the embodiment, the columnar semiconductor CLmn is formed in the n⁺ region formed in the P⁻-type region (P⁻ well region) Ba1 on the semiconductor substrate Ba.

Furthermore, the source line SL (n⁺ region formed in the P⁻ well region Ba1 of the semiconductor substrate Ba) is connected to a source of the source side selection transistor SSTrmn. Further, the bit line BL is connected to a drain of the drain side selection transistor SDTrmn.

Each memory transistor MTrmn has the columnar semiconductor CLmn, an electric charge accumulation layer formed so as to surround the columnar semiconductor CLmn, and the word line WL formed so as to surround the electric charge accumulation layer. The word line WL serves as a control gate of the memory transistor MTrmn.

In the non-volatile semiconductor memory device 100 having the above configuration, voltages for the bit lines BL1 to BL3, the drain side selection gate line SGD, the word lines WL1 to WL4, the source side selection gate line SGS, and the source line SL are controlled by the bit line driving circuit (not shown in the drawing), the drain side selection gate line driving circuit 15, the word line driving circuit 13, the source side selection gate line driving circuit 14 and the source line driving circuit (not shown in the drawing). That is, electric charge of the electric charge accumulation layer of predetermined memory transistor MTrmn is controlled; and accordingly, writing, and erasing are executed.

### Configuration of Memory String MS of Non-Volatile Semiconductor Memory Device 100 According to First Embodiment

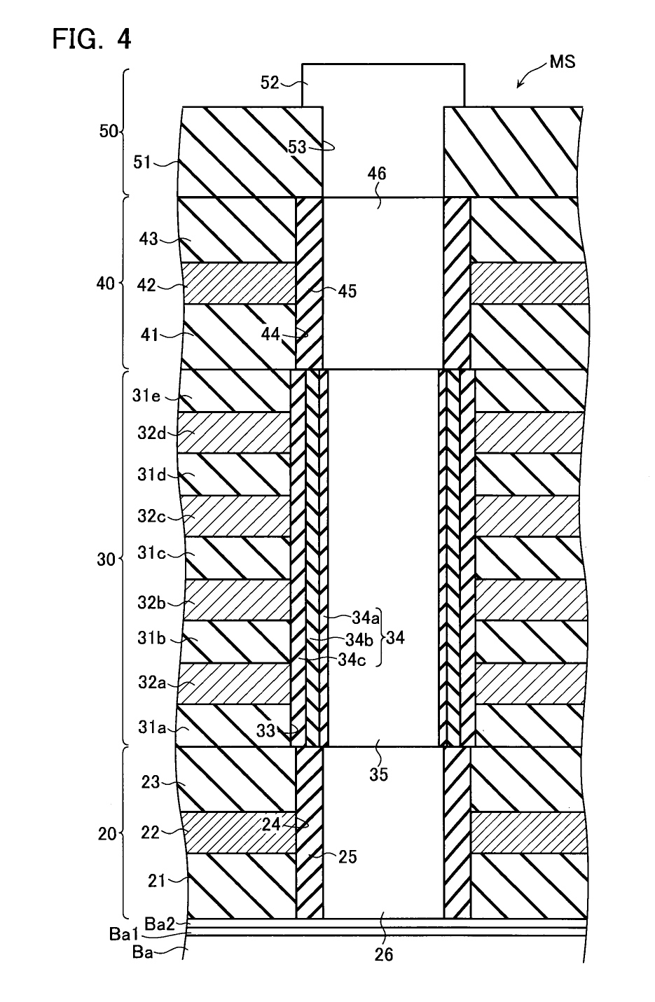

Next, the configuration of the memory string MS of the non-volatile semiconductor memory device 100 will be described with reference to FIG. 4. FIG. 4 is a cross-sectional view showing the memory string MS of the non-volatile semiconductor memory device 100 according to the first embodiment.

As shown in FIG. 4, the non-volatile semiconductor memory device 100 (memory string MS) has a source side selection transistor layer 20, a memory transistor layer 30, a drain side selection transistor layer 40, and an interconnection layer 50, formed on the semiconductor substrate Ba from a lower layer to an upper layer in the memory transistor region 12. The source side selection transistor layer 20 serves as the source side selection transistor SSTrmn. The memory transistor layer 30 serves as a plurality of memory transistors MTrmn which are connected in series. The drain side selection transistor layer 40 serves as the drain side selection transistor SDTrmn.

The P⁻-type region (P⁻ well region) Ba1 is formed on the semiconductor substrate Ba. Furthermore, the n⁺ region (source line region) Ba2 is formed on the P⁻-type region Ba1.

The source side selection transistor layer 20 has a source side first insulating layer 21, a source side conductive layer (second conductive layer) 22, and a source side second insulating layer 23, those of which are laminated in order on the semiconductor substrate Ba.

The source side first insulating layer 21, the source side conductive layer 22, and the source side second insulating layer 23 are formed in the memory transistor region 12 so as to be two-dimensionally extended parallel to the semiconductor substrate Ba. The source side first insulating layer 21, the source side conductive layer 22, and the source side second insulating layer 23 are divided for each predetermined region (erase unit) within the memory transistor region 12.

The source side first insulating layer 21 and the source side second insulating layer 23 are configured by silicon oxide (SiO₂). The source side conductive layer 22 is configured by P⁺-type polysilicon (p-Si).

Furthermore, a source side hole 24 is formed so as to pass through the source side second insulating layer 23, the source side conductive layer 22, and the source side first insulating layer 21. A source side gate insulating layer (gate insulating layer) 25 and a source side columnar semiconductor layer (second semiconductor layer) 26 are formed on the side facing the source side hole 24.

The source side gate insulating layer 25 is formed between the side of the source side columnar semiconductor layer 26 and the source side second insulating layer 23, the source side conductive layer 22, and the source side first insulating layer 21. The source side columnar semiconductor layer 26 is formed in a columnar shape which extends substantially perpendicular to the semiconductor substrate Ba. The source side columnar semiconductor layer 26 is formed so as to come in contact with a memory columnar semiconductor layer 35 to be described later. The source side gate insulating layer 25 is configured by silicon oxide (SiO₂). The source side columnar semiconductor layer 26 is formed by polysilicon (p-Si).

Incidentally, in the configuration of the above source side selection transistor 20, the configuration of the source side conductive layer 22 is that, that is to say, the source side conductive layer 22 is formed so as to sandwich the source side gate insulating layer 25 together with the source side columnar semiconductor layer 26.

Furthermore, in the source side selection transistor layer 20, the source side conductive layer 22 serves as the source side selection gate line SGS. Further, the source side conductive layer 22 serves as a control gate of the source side selection transistor SSTrmn.

The memory transistor layer 30 has first to fifth inter-wordline insulating layers 31a to 31e provided on the upper side of the source side second insulating layer 23 and first to fourth wordline conductive layers 32a to 32d (first conductive layer) provided between the top and the bottom of the first to fifth inter-wordline insulating layers 31a to 31e.

The first to fifth inter-wordline insulating layers 31a to 31e and the first to fourth wordline conductive layers 32a to 32d are formed so as to be two-dimensionally extended parallel to the semiconductor substrate Ba and formed in a stepwise shape at an end portion in the row direction.

The first to fifth inter-wordline insulating layers 31a to 31e are configured by silicon oxide (SiO₂). The first to fourth wordline conductive layers 32a to 32d are configured by n⁺-type polysilicon (p-Si). That is, the first to fourth wordline conductive layers 32a to 32d are configured by material smaller in work function than P⁺-type polysilicon.

In manufacturing, the first to fourth wordline conductive layers 32a to 32d are formed by “in situ doping” which makes polysilicon deposit by doping an N-type impurity ion. Alternatively, the first to fourth wordline conductive layers 32a to 32d are formed by “sequential doping” which makes the N-type impurity ion dope after the polysilicon has been deposited.

Furthermore, in the memory transistor layer 30, a memory hole 33 is formed so as to pass through the first to fifth inter-wordline insulating layers 31a to 31e and the first to fourth wordline conductive layers 32a to 32d. The memory hole 33 is provided at a position which conforms to the source side hole 27. A memory gate insulating layer 34 and a memory columnar semiconductor layer (first semiconductor layer) 35 are formed in order on the side within the memory side hole 33.

The memory gate insulating layer 34 has a tunnel insulating layer 34a, an electric charge accumulation layer 34b which accumulates electric charge, and a block insulating layer 34c in order from the side of the columnar semiconductor layer 35. The tunnel insulating layer 34a and the block insulating layer 34c are formed by silicon oxide (SiO₂). The electric charge accumulation layer 34b is formed by silicon nitride (SiN). Incidentally, the block insulating layer 34c is formed thicker than the tunnel insulating layer 34a.

The memory columnar semiconductor layer 35 is formed so as to extend in a substantially vertical direction to the semiconductor substrate Ba. The memory columnar semiconductor layer 35 is formed so as to come in contact with the source side columnar semiconductor layer 26 and a drain side columnar semiconductor layer 46 to be described later. The memory columnar semiconductor layer 35 is configured by polysilicon (p-Si).

Incidentally, in the above memory transistor 30, the configuration of the first to fourth wordline conductive layers 32a to 32d are that, that is to say, the first to fourth wordline conductive layers 32a to 32d are formed so as to sandwich the tunnel insulating layer 34a, the electric charge accumulation layer 34b, and the block insulating layer 34c together with the memory columnar semiconductor layer 35.

Furthermore, in the memory transistor layer 30, the first to fourth wordline conductive layers 32a to 32d serve as the word lines WL1 to WL4. Further, the first to fourth wordline conductive layers 32a to 32d serve as the control gate of the memory transistor MTrmn.

The drain side selection transistor layer 40 has a drain side first insulating layer 41, a drain side conductive layer (second conductive layer) 42, and a drain side second insulating layer 43, those of which are laminated in order on the fifth inter-wordline insulating layer 31e.

The drain side first insulating layer 41, the drain side conductive layer 42, and the drain side second insulating layer 43 are formed so as to extend parallel to the semiconductor substrate Ba. The drain side first insulating layer 41, the drain side conductive layer 42, and the drain side second insulating layer 43 are formed at a position which conforms to an upper portion of the memory columnar semiconductor layer 35 and extended in the row direction formed in line shapes repeatedly provided in the column direction.

The drain side first insulating layer 41 and the drain side second insulating layer 43 are formed by silicon oxide (SiO₂) The drain side conductive layer 42 is formed by P⁺-type polysilicon (p-Si).

Furthermore, in the drain side selection transistor layer 40, a drain side hole 44 is formed so as to pass through the drain side second insulating layer 43, the drain side conductive layer 42, and the drain side first insulating layer 41. The drain side hole 44 is provided at a position which conforms to the memory hole 33. A drain side gate insulating layer 45 (gate insulating layer) and the drain side columnar semiconductor layer (second semiconductor layer) 46 are provided in order on the side facing the drain side hole 44.

The drain side gate insulating layer 45 is formed between the side of the drain side columnar semiconductor layer 46 and the drain side second insulating layer 43, the drain side conductive layer 42, and the drain side first insulating layer 41. The drain side columnar semiconductor layer 46 is formed in a columnar shape which extends substantially perpendicular to the semiconductor substrate Ba. The drain side columnar semiconductor layer 46 is formed so as to come in contact with the memory columnar semiconductor layer 35. The drain side gate insulating layer 45 is configured by silicon oxide (SiO₂). The drain side columnar semiconductor layer 46 is configured by polysilicon (p-Si).

Incidentally, in the configuration of the above drain side selection transistor layer 40, the configuration of the drain side conductive layer 42 is that, that is to say, the drain side conductive layer 42 is formed so as to sandwich the drain side gate insulating layer 45 together with the drain side columnar semiconductor layer 46.

Furthermore, in the drain side selection transistor layer 40, the drain side conductive layer 42 serves as the drain side selection gate line SGD. Further, the drain side conductive layer 42 serves as a control gate of the drain side selection transistor SDTrmn.

The interconnection layer 50 has an interconnection insulating layer 51 and an interconnection conductive layer 52 laminated in order on the upper side of the drain side second insulating layer 43. An interconnection trench 53 is provided in the interconnection insulating layer 51 so as to pass through the interconnection insulating layer 51. The interconnection conductive layer 52 is formed so as to embed the interconnection trench 53.

The interconnection insulating layer 51 is configured by silicon oxide (SiO₂). The interconnection conductive layer 52 is configured by titanium-titanium nitride (Ti—TiN) and tungsten (W). The interconnection conductive layer 52 serves as the bit line BL.

### Method of Manufacturing Non-Volatile Semiconductor Memory Device 100 According to First Embodiment

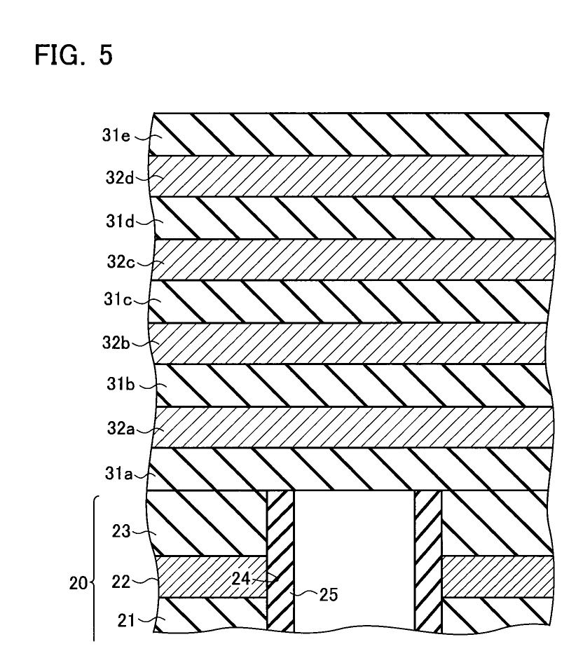

Next, a method of manufacturing the non-volatile semiconductor memory device 100 according to the first embodiment will be described with reference to FIGS. 5 to 8. FIGS. 5 to 8 are cross-sectional views showing manufacturing processes of the non-volatile semiconductor memory device 100 according to the first embodiment. Incidentally, a manufacturing method shown below shows only a manufacturing process of the memory transistor layer 30.

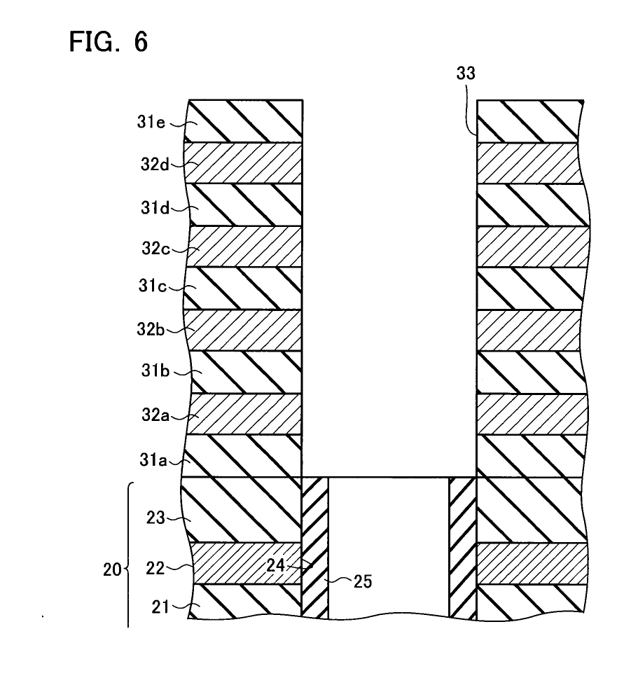

First, as shown in FIG. 5, silicon oxide and N⁺-type polysilicon are laminated in order on an upper layer of the source side selection transistor layer 20 to be formed the first to fifth inter-wordline insulating layers 31a to 31e and the first to fourth wordline conductive layers 32a to 32d. Next, as shown in FIG. 6, the memory hole 33 is formed so as to pass through the first to fifth inter-wordline insulating layers 31a to 31e and the first to fourth wordline conductive layers 32a to 32d.

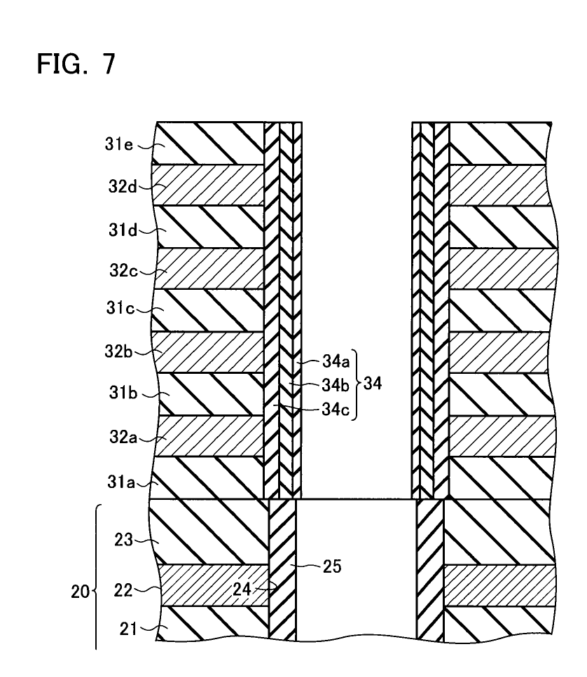

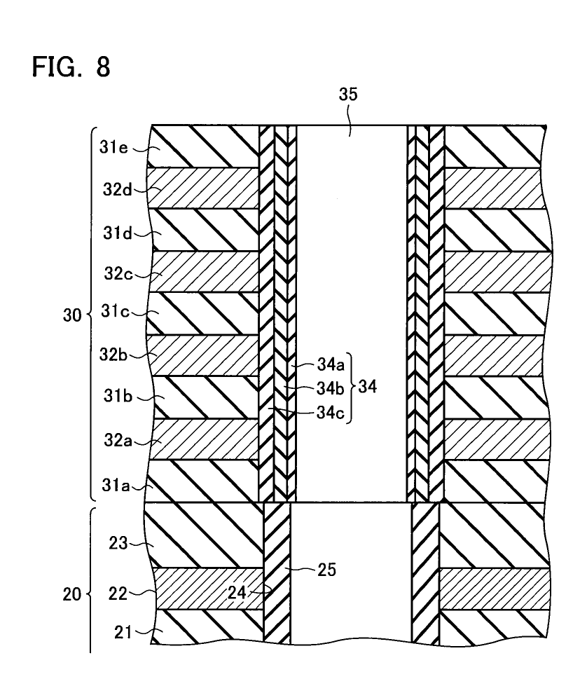

Subsequently, as shown in FIG. 7, silicon oxide, silicon nitride, and silicon oxide are deposited in order on a sidewall facing the memory hole 33 to be formed the memory gate insulating layer 34. Then, as shown in FIG. 8, polysilicon is deposited so as to embed the memory hole 33. By this step, the memory columnar semiconductor layer 35 is formed. The memory gate insulating layer 34 and the memory columnar semiconductor layer 35 are formed using low temperature deposition or the like by atomic layer deposition (ALD).

### Effects of Non-Volatile Semiconductor Memory Device 100 According to First Embodiment

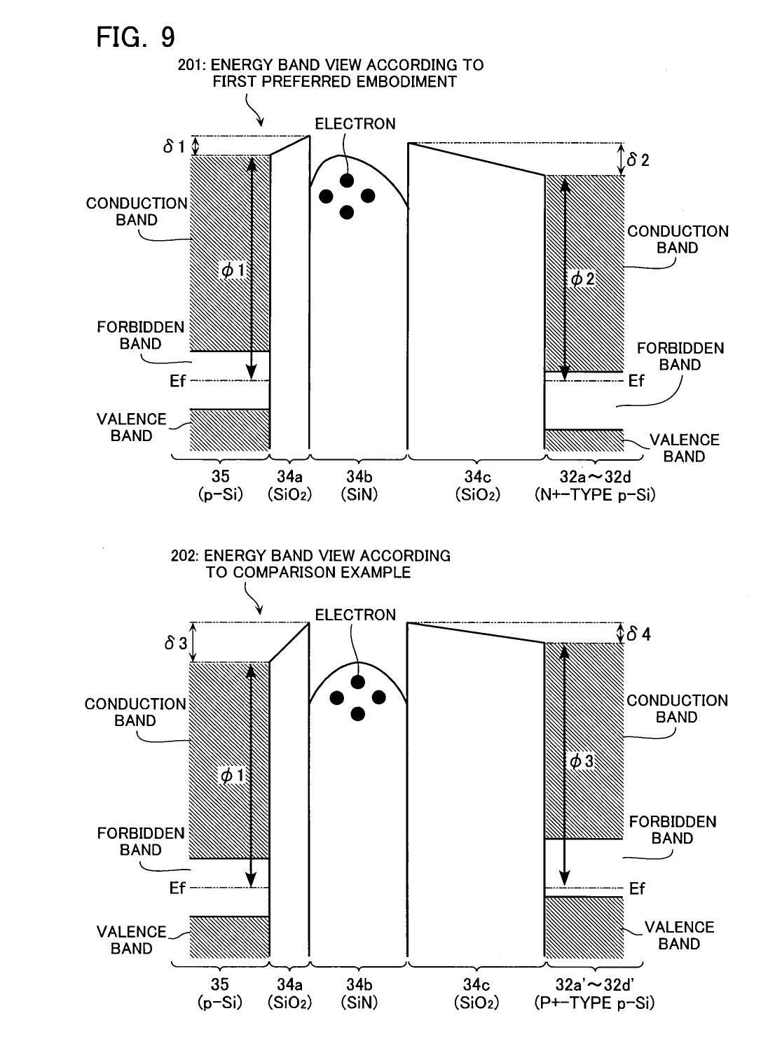

Next, effects of the non-volatile semiconductor memory device 100 according to the first embodiment will be described with reference to FIG. 9. FIG. 9 is an energy band view for explaining effects of the non-volatile semiconductor memory device 100 according to the first embodiment. FIG. 9 shows an energy band view according to the first embodiment (reference numeral 201) and an energy band view according to a comparison example (reference numeral 202). The comparison example shown in FIG. 9 is different from the first embodiment in that the comparison example has first to fourth wordline conductive layers 32a′ to 32d′ configured by Ps-type polysilicon (p-Si) in place of the first to fourth wordline conductive layers 32a to 32d configured by N⁺-type polysilicon.

In the energy band view according to the comparison example (reference numeral 202), the memory columnar semiconductor layer 35 is configured by polysilicon; and the first to fourth wordline conductive layers 32a′ to 32d′ are configured by P⁺-type polysilicon. Therefore, a work function φ3 (up to 5.5 eV) of the first to fourth wordline conductive layers 32a′ to 32d′ is larger than a work function φ1 of the memory columnar semiconductor layer 35. A potential barrier δ3 is generated in the tunnel insulating layer 34a by these work functions φ1 and φ3, and a work function of the electric charge accumulation layer 34b in which electrons are accumulated. Consequently, a potential barrier δ4 is generated in the block insulating layer 34c.

On the other hand, in the energy band view according to the first embodiment (reference numeral 201), the first to fourth wordline conductive layers 32a to 32d are configured by N⁺-type polysilicon. Therefore, a work function φ2 (up to 4.7 eV) of the first to fourth wordline conductive layers 32a to 32d according to the first embodiment becomes a value smaller than the work function φ3 of the first to fourth wordline conductive layers 32a′ to 32d′ configured by P⁺-type polysilicon according to the comparison example. Incidentally, the memory columnar semiconductor layer 35 according to the first embodiment has the work function φ1. A potential barrier δ1 is generated in the tunnel insulating layer 34a by these work functions φ1 and φ2, and the work function of the electric charge accumulation layer 34b in which electrons are accumulated. Consequently, a potential barrier δ2 is generated in the block insulating layer 34c.

The potential barrier δ1 of the tunnel insulating layer 34a according to the first embodiment become a value smaller than the potential barrier δ3 of the tunnel insulating layer 34a according to the comparison example by the influence of the work function φ2 of the above first to fourth wordline conductive layers 32a to 32d.

Therefore, the non-volatile semiconductor memory device 100 according to the first embodiment is smaller in potential barrier generated in the tunnel insulating layer 34a than the comparison example, so electric field applied to the insulating layer is small. Therefore, electron emission from the electric charge accumulation layer 34b to the memory columnar semiconductor layer 35 can be suppressed than the comparison example. That is, the non-volatile semiconductor memory device 100 according to the first embodiment can be enhanced in data retention characteristics than the comparison example.

On the other hand, in the source side selection transistor layer 20, the source side conductive layer 22 is configured by P⁺-type polysilicon. Therefore, cut off characteristics of the source side selection transistor SSTrmn can be retained. Furthermore, similarly, in the drain side selection transistor layer 40, the drain side conductive layer 42 is configured by P⁺-type polysilicon. Therefore, cut off characteristics of the drain side selection transistor SDTrmn can be retained.

Besides, the non-volatile semiconductor memory device 100 according to the first embodiment is capable of high integration as shown in the above layered structure. In addition, in the non-volatile semiconductor memory device 100, the respective layers serving as the memory transistor MTrmn, and the respective layers serving as the source side selection transistor SSTrmn and the drain side selection transistor layer SDTrmn can be manufactured in the number of predetermined lithography processes irrespective of the number of lamination layers. That is, it is possible to manufacture the non-volatile semiconductor memory device 100 inexpensively.

### Second Embodiment

### Configuration of Memory String MSa of Non-Volatile Semiconductor Memory Device According to Second Embodiment

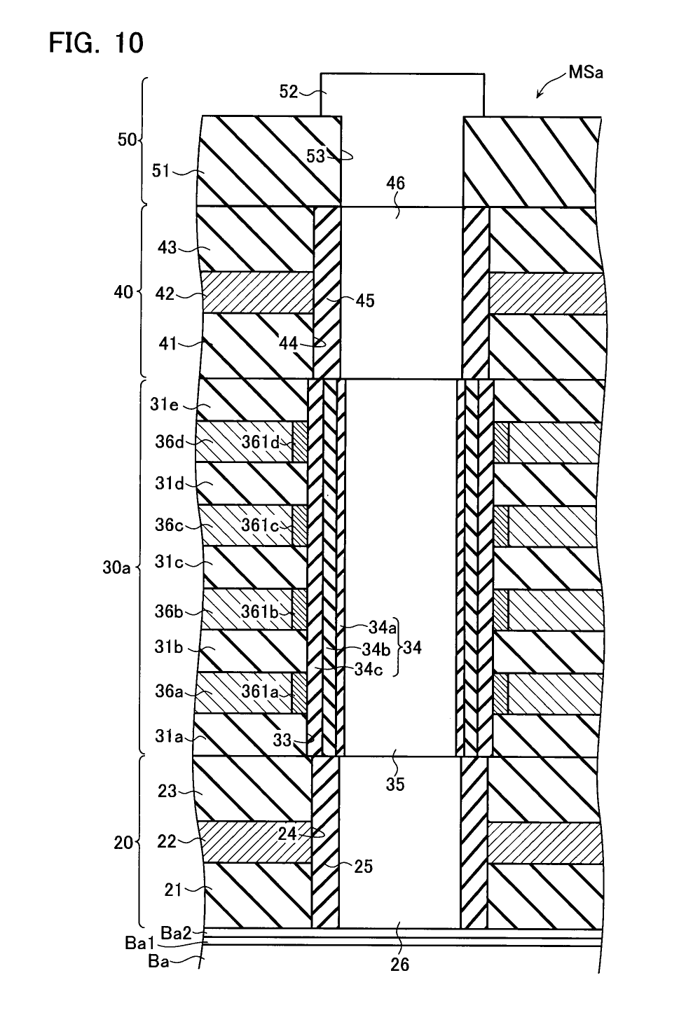

Next, a configuration of a memory string MSa of a non-volatile semiconductor memory device according to a second embodiment will be described with reference to FIG. 10. FIG. 10 is a cross-sectional view showing the memory string MSa of the non-volatile semiconductor memory device according to the second embodiment of the present invention. The memory string MSa according to the second embodiment has a memory transistor layer 30a different from the first embodiment. Other configuration is the same as the first embodiment. Incidentally, in the second embodiment, the same reference numerals are given to those having the same configuration as the first embodiment, and their description will not be repeated.

The memory transistor layer 30a has first to fourth word line conductive layers 36a to 36d different from the first embodiment. The first to fourth word line conductive layers 36a to 36d are configured by polysilicon different from the first embodiment. Further, sides 361a to 361d of first to fourth word line conductive layers 36a to 36d facing a block insulating layer 34c are configured by silicide. For example, the sides 361a to 361d of the first to fourth word line conductive layers 36a to 36d are configured by any one of HfSi (4.29 eV), ZrSi₂ (4.32 eV), TaSi₂ (4.37 eV), TiSi₂ (4.38 eV), VSi (4.38 eV), WiSi₂ (4.43 eV), CrSi₂ (4.42 eV), MoSi₂ (4.44 eV), NiSi (4.54 eV), and CoSi₂ (4.51 eV). Incidentally, the values in the above parentheses are work functions of respective materials.

Manufacture of the first to fourth word line conductive layers 36a to 36d according to the second embodiment is performed by the following process. That is, first, polysilicon serving as the first to fourth word line conductive layers 36a to 36d is deposited, and then, a memory hole 33 is formed by passing through the polysilicon. Then, Ni/Co/Ti or the like is deposited on a surface of the polysilicon facing the memory hole 33 and activated. Accordingly, the surface of the polysilicon facing the memory hole 33 is silicided. The first to fourth word line conductive layers 36a to 36d having the sides 361a to 361d configured by silicide are formed by the above process. After that, a memory gate insulating layer 34 and a memory columnar semiconductor layer 35 are formed in the memory hole 33 using low temperature deposition or the like by atomic layer deposition (ALD) Atomic Layer Deposition and avoiding a thermal process equal to or more than 500° C.

### Effects of Non-Volatile Semiconductor Memory Device According to Second Embodiment

The non-volatile semiconductor memory device according to the second embodiment has the first to fourth word line conductive layers 36a to 36d whose sides 361a to 361d are configured by material (silicide) smaller in work function than P⁺-type polysilicon. Therefore, the non-volatile semiconductor memory device according to the second embodiment exhibits the same effects as the first embodiment.

### Other Embodiment

As described above, the embodiments of the non-volatile semiconductor memory device are described However, the present invention is not limited to the above embodiments, and various modifications, addition, and replacement may be made without departing from the spirit or scope of the present invention.

For example, in the first embodiment, the first to fourth wordline conductive layers 32a to 32d are configured by N⁺-type polysilicon (p-Si). Furthermore, in the second embodiment, the first to fourth word line conductive layers 36a to 36d have their sides 361a to 361d configured by silicide. However, the first to fourth wordline conductive layers 32a to 32d (36a to 36d) may be configured by material smaller in work function than P⁺-type polysilicon (p-Si).

Consequently, the first to fourth wordline conductive layers 32a to 32d may be configured by metal. For example, the first to fourth wordline conductive layers 32a to 32d may be configured by any one of Al (4.1 eV), TiAl (4.6 eV), Pd (4.9 eV), and W (4.6 eV). Incidentally, the values in the above parentheses are work functions of respective materials.

Furthermore, for example, the above embodiments each has the source side columnar semiconductor layer 26 configured in a columnar shape, the memory columnar semiconductor layer 35 configured in a columnar shape, and the drain side columnar semiconductor layer 46 configured in a columnar shape, formed from the lower layer to the upper layer. However, the memory columnar semiconductor layer 35 may be formed in a U-shape in seeing from a direction orthogonal to a lamination direction. Furthermore, in this case, the source side columnar semiconductor layer 26 and the drain side columnar semiconductor layer 46 may be formed on two upper surfaces (end portions) of the U-shaped memory columnar semiconductor layer.

What is claimed is:

1. A non-volatile semiconductor memory device comprising a memory string which is electrically rewritable and includes a plurality of memory cells connected in series,
the memory string comprising:
a plurality of first conductive layers which are extended parallel to a substrate and laminated;
a first semiconductor layer which is formed so as to pass through the plurality of the first conductive layers; and
an electric charge accumulation layer which is formed between the first conductive layer and the first semiconductor layer and is configured so as to be able to accumulate electric charge,
the first conductive layer being configured by material smaller in work function than P⁺-type polysilicon.

2. The non-volatile semiconductor memory device according to claim 1,
wherein the first conductive layer is configured by N⁺-type polysilicon.

3. The non-volatile semiconductor memory device according to claim 1,
wherein the first conductive layer is configured by silicide.

4. The non-volatile semiconductor memory device according to claim 3,
wherein the silicide is configured by any one of HfSi, ZrSi₂, TaSi₂, TiSi₂, VSi, WiSi₂, CrSi₂, MoSi₂, NiSi, and CoSi₂.

5. The non-volatile semiconductor memory device according to claim 1,
wherein the first conductive layer is configured by metal.

6. The non-volatile semiconductor memory device according to claim 5,
wherein the metal is configured by any one of Al, TiAl, Pd, and W.

7. The non-volatile semiconductor memory device according to claim 1,
wherein the memory string includes a transistor connected in series to the memory cells and controls whether or not a current is to be supplied to the memory string,
the transistor including:
a second conductive layer which is extended parallel to the substrate;
a second semiconductor layer formed so as to pass through the second conductive layer and come in contact with the first semiconductor layer; and
a gate insulating layer formed between the second conductive layer and the second semiconductor layer,
the second conductive layer being configured by P⁺-type polysilicon.

8. The non-volatile semiconductor memory device according to claim 7,
wherein the second conductive layer is formed on a lower layer of the first conductive layer, and
the second semiconductor layer is formed so as to come in contact with a lower surface of the first semiconductor layer.

9. The non-volatile semiconductor memory device according to claim 7,
wherein the second conductive layer is formed on an upper layer of the first conductive layer, and
the second semiconductor layer is formed so as to come in contact with an upper surface of the first semiconductor layer.

10. The non-volatile semiconductor memory device according to claim 1,
wherein the memory string includes first and second transistors which are connected in series to the memory cells and control whether or not a current is to be supplied to the memory string,
the first transistor including:
a second conductive layer which is extended parallel to the substrate and formed on a lower layer of the first conductive layer;
a second semiconductor layer which is formed so as to pass through the second conductive layer and come in contact with a lower surface of the first semiconductor layer; and
a first gate insulating layer which is formed between the second conductive layer and the second semiconductor layer,
the second transistor including:
a third conductive layer which is extended parallel to the substrate and formed on an upper layer of the first conductive layer;
a third semiconductor layer which is formed so as to pass through the third conductive layer and come in contact with an upper surface of the first semiconductor layer; and
a second gate insulating layer which is formed between the third conductive layer and the third semiconductor layer, and
the second conductive layer and the third conductive layer being configured by P⁺-type polysilicon.

11. A method of manufacturing a non-volatile semiconductor memory device having memory cells which are electrically rewritable and are connected in series, the method of manufacturing the non-volatile semiconductor memory device comprising:
laminating a plurality of conductive layers on a substrate;
forming a hole so as to pass through the plurality of the conductive layers;
forming an electric charge accumulation layer on a side wall facing the hole; and
forming a semiconductor layer so as to embed the hole, the conductive layer being configured by material smaller in work function than P⁺-type polysilicon.

12. The method of manufacturing the non-volatile semiconductor memory device according to claim 11,
wherein the conductive layer is configured by N⁺-type polysilicon.

13. The method of manufacturing the non-volatile semiconductor memory device according to claim 11,
wherein the conductive layer is configured by silicide.

14. The method of manufacturing the non-volatile semiconductor memory device according to claim 13,
wherein the silicide is configured by siliciding a surface of the conductive layer facing the hole before the electric charge accumulation layer is formed.

15. The method of manufacturing the non-volatile semiconductor memory device according to claim 13,
wherein the silicide is configured by any one of HfSi, ZrSi₂, TaSi₂, TiSi₂, VSi, WiSi₂, CrSi₂, MoSi₂, NiSi, and CoSi₂.

16. The method of manufacturing the non-volatile semiconductor memory device according to claim 11,
wherein the conductive layer is configured by metal.

17. The method of manufacturing the non-volatile semiconductor memory device according to claim 16,
wherein the metal is configured by any one of Al, TiAl, Pd, and W.

18. The method of manufacturing the non-volatile semiconductor memory device according to claim 11,
wherein the electric charge accumulation layer and the semiconductor layer are formed by ALD.

19. The method of manufacturing the non-volatile semiconductor memory device according to claim 18,
wherein the electric charge accumulation layer and the semiconductor layer are formed avoiding a thermal process equal to or more than 500° C.
